(19) United States
(12) Patent Application Publication
(10) Pub. No.: US 2023/0240088 A1
(43) Pub. Date: Jul. 27, 2023

(54) AMBIPOLAR TRANSISTOR STRUCTURE AND ELECTRONIC DEVICE

(71) Applicant: Technion Research and Development Foundation Ltd., Haifa (IL)

(72) Inventors: Tanmoy SARKAR, Kolkata (IN); Gitti L. FREY, Haifa (IL)

(21) Appl. No.: 17/819,061

(22) Filed: Aug. 11, 2022

Related U.S. Application Data
(60) Provisional application No. 63/233,005, filed on Aug. 13, 2021.

(51) Int. Cl. H10K 10/46; H10K 19/10

(52) U.S. Cl. CPC H10K 10/466; H10K 19/10

(57) ABSTRACT

A transistor structure is presented comprising: an organic semiconductor channel region, and source and drain electrodes in electrical contact with said organic semiconductor channel region, wherein at least one of said source and drain electrodes is formed by spaced apart regions of a first metallic material separated by regions of a second metallic material such that regions of the first and second metallic materials are in contact with the organic semiconductor channel region, said first metallic material being selected as having work function substantially similar to HOMO energy level of said organic semiconductor channel region and said second metallic material being selected as having work function substantially similar to LUMO energy level of said organic semiconductor channel region, thereby enabling selective injections of electrons or holes into said channel region.

### TECHNOLOGICAL FIELD

The present invention relates to configurations of transistor elements and electronic devices using such transistor elements and specifically related ambipolar transistor configuration.

### BACKGROUND

Transistors are semiconductor based electronic elements that enable amplification and/or switching of electric power. Typical transistor elements are configured to enable transmission of electrons or holes, designating an inherent direction for power transmission.

Ambipolar transistors can transport holes and electrons, separately or concurrently, within the semiconducting channel. The operation of the ambipolar transistor requires that the semiconducting material composing the channel of the transistor is capable of efficiently transporting both charge carriers, and the suitable alignment of energy levels between the semiconductor and the electrodes enable efficient injection of both carriers from the electrodes into the semiconducting channel. Inorganic semiconducting materials, such as silicon and GaAs, can conduct either holes or electrons, depending on the type of doping.

Organic field effect transistors (OFETs) utilize channel formed of one or more organic semiconductors. Such OFETs sparked great interest providing contemporary applications in non-traditional areas such as clothing, paper, flexible and rollable displays, bio-integrated applications. Most organic semiconducting materials with relatively narrow bandgaps (1-2 eV) are generally capable of conducting electrons and holes alternatively or simultaneously.

### GENERAL DESCRIPTION

There is a need in the art for transistor configuration enabling selective and simultaneous transmission of electrons and holes. As indicated above, Organic semiconductor materials with energy gap of 1-2 eV have energy level structure that may enable transmission of electrons and holes. Some organic semiconductor materials provide higher energy gap and may also be used in the technique described hereinbelow.

The present invention utilizes such organic semiconductor materials to form the channel region of the transistor. Also, the present invention utilizes electrode configuration enabling injection and collection of electrons and holes into the organic semiconductor channel.

Accordingly, the present invention provides a transistor structure comprising an organic semiconductor channel region and source and drain electrodes being in electrical contact with the organic semiconductor channel region. The organic semiconductor channel region comprises one or more organic semiconductor material compositions enabling transmission of charged particles therethtough. To enable injection of both electrons and holes into the channel region, at least one of the source and drain electrodes, and preferably both electrodes, is formed by spaced apart regions of first and second metallic materials both being in electrical contact with the channel region. The first and second metallic materials are selected as having work functions that are relatively close to, respectively, HOMO (Highest Occupied Molecular Orbital) and LUMO (lowest unoccupied molecular orbital) energy levels of at least one of the organic semiconductor materials of the channel region. This configuration enables selective injections of electrons or holes into said channel region.

More specifically, in configurations where the organic semiconductor channel region includes more than one organic material composition, the first and second metallic materials are selected in accordance with HOMO and LUMO energy levels most suitable for transmission of electrons and holes. Typically, such energy levels relate to the highest HOMO energy level between the organic semiconductor materials for transmission of holes and to the lowest LUMO level between the organic semiconductor materials for transmission of electrons.

Further, the electrode is configured to provide electrical contact of first and second metallic materials of the electrode with the semiconductor channel region. This enables injection of positive charges (holes) from one metallic material of the electrode into the channel, where the metallic material has work function that is relatively close to HOMO energy level of at least one organic semiconductor material of the channel region. Additionally, this configuration enables injection of negative charged (electrons) from the other metallic material, where it has work function that is relatively close to LUMO energy level of at least one organic semiconductor material of the channel region.

Generally, the first and second metallic materials are selected as having work function as close as 0.2 eV, or preferably 0.1 eV, to the respective HOMO or LUMO energy levels.

In some embodiments, transistor structure may comprise thin organic or inorganic interlayers (alignment interlayers) between the metal contact and the organic semiconductor selected to tune the energy levels variation along the electrode/semiconductor interface. The interlayers may be formed by migration of suitable organic or inorganic molecules from the material of the organic semiconductor channel onto the interface between the organic semiconductor channel and the electrodes. The alignment interlayers may comprise organic molecules comprising moieties selected as having affinity to the first and/or second metallic materials of the electrode(s). The moieties provide alignment of work function of the metallic materials with the respective energy level of the HOMO and/or LUMO energy levels of said organic semiconductor channel region.

It should be noted that the organic semiconductor material forming the channel region may include one or more types of material compositions. In this connection, a first organic semiconductor material composition may be better tuned for transmitting electrons (i.e. n-type) and a second organic semiconductor material composition may be better tuned for transmitting holes (i.e. p-type). As indicated above, in such configurations, the first and second metallic materials of the electrodes are selected in accordance with energy levels of the different organic semiconductor materials suitable for transmission of the respective charge carriers. In this connection, the present technique as described herein refers to organic semiconductor material forming the channel region, and its respective HOMO and LUMO energy levels, but should be interpreted broadly for the use of a mixture of two or more organic semiconductor materials having different HOMO and LUMO energy levels as indicated above.

To this end, the electrode, being source and/or drain electrode, is formed by a patterned structure having a contact surface configured to be in electrical contact with the channel region. The contact surface is formed by spaced apart regions of first metallic material separated by regions of a second metallic material. The spaced apart regions may be formed as islands of a first metallic material separated between them by the second metallic material. In some configurations the first and second metallic materials may be arranged in interdigital configuration or other configurations of interlaced/alternating regions of the first and second metallic materials.

In some preferred configurations, both source and drain electrodes are configured with patterned interface providing electrical contacts of first and second metallic materials with the semiconductor channel region. This configuration enables injection and collection of both electrons and holes through the channel region, and thereby enables ambipolar operation of the transistor element.

Generally, the transistor structure further comprises a gate electrode configured to apply electric field onto the channel region to thereby modulate transmission of charges through the channel region. Selection of voltage applied by the gate electrode (gate voltage) enables selection of transmission of electrons or holes through the channel region thus enabling selective ambipolar operation of the transistor structure.

Further, in some embodiments, the present invention provides an electronic device including the transistor structure having a layered configuration. The device comprises a first electrode layer, an insulator layer applied on the first electrode layer, an organic semiconductor layer (channel) applied on the insulator layer and a second electrode layer applied on said organic semiconductor layer. The second electrode layer is formed by at least two spaced apart electrodes being in electrical contact with said organic semiconductor layer while separated between them. At least one of these spaced apart electrodes is formed by spaced apart regions of a first metallic material separated by regions of a second metallic material such that regions of the first and second metallic materials are in contact with the organic semiconductor layer. The first and second metallic materials are selected as having work function substantially similar to respective one of the HOMO and LUMO energy levels of the organic semiconductor layer to enable selective injections of electrons or holes into said organic semiconductor layer.

The electronic device and transistor structure described herein enables simplified configurations of complex electronic devices. More specifically, the transistor structure enables selective transmission of electrons or holes thus enabling the use of similar transistor structures for opposite functionalities within a circuit. For example, the use of ambipolar transistor structure as described herein, enables formation of inverter or NOT gate using transistor structures having similar configuration, while varying output of the transistor directly in accordance with gate voltage thereof.

For example, the present technique provides a transmission gate formed of a single transistor unit. The transmission gate allows transmission of current in first and second directions, or blocks transmission of current in response to control signal (gate voltage). More specifically, at blocking control signal (e.g. zero gate voltage) the transmission gate blocks current transmission, at positive control signal (B+Δ) the transmission gate allows current in one direction and at negative control signal (B−Δ) the transmission gate allows current in another direction.

In some additional examples, the present invention provides a logic gate such as an inverter unit (e.g. CMOS or CMOS-like inverter), comprising first and second ambipolar transistor structures having similar configuration as described herein. The transistor structures are connected in series between first and second power connections (e.g. ground and bias voltage or first and second bias voltages) and providing output connection between the first and second transistor structures. Gate electrodes of the first and second transistor structures are connected in parallel to an input line such that input voltage greater than an assigned threshold (based on bias voltage) activates the first transistor structure, and input voltage below the threshold will active the second transistor structure.

Thus, according to yet further aspect, the invention provides a logic gate comprising a first and a second transistor units having similar ambipolar configuration, where the first and second transistor units are electrically connected in series between selected input voltage between corresponding source and drain electrodes thereof, an output connector is provided between said first and second transistor units, and gate electrodes of the first and second transistor units are commonly connected to an input connector, such that said logic gate provides inversion of input signal.

The organic semiconductor channel may be formed of various organic semiconductor materials and may be formed of polymeric material and/or small molecules. The organic semiconductor may be formed of any one of the following polymers: DPP derivatives, such as DPP-T-TT, F8BT, NDI derivatives, polythieno[3,4-b]-thiophene-co-benzodithiophene (PTB7), Pentacene derivatives, CuPc, rubrene, PDI derivatives, C8-BTBT, BBTNDT, C60 and derivatives, indigo or other organic semiconductor materials. In some configurations the organic semiconductor material of the channel may be a mixture of two or more organic semiconductor material compositions, for example such mixture may be selected from: PNDI(2OD)2T (n-type) and DPP3T (p-type), PCBM and P3HT, PDBPyBT and DPP3T, P3HT or PTB7, PDBPyBT and IDTBT, PNDI(2OD)2T and PBTTT-C14, PCBM and Pentacene, IDTIC and DNTT, ITIC and DPP-DTE-CN-n, or various other combinations of p- and n-type organic semiconductor materials. It should be noted that the channel region may be formed by a single organic semiconductor material, being polymeric or small particles. Alternatively, the channel region may be formed of a mixture of two or more organic semiconductor materials, being both polymers, both small molecules or a combination of polymer and small molecules.

Thus, according to a broad aspect, the present invention provides a transistor structure comprising organic semiconductor channel region and source and drain electrodes in electrical contact with said organic semiconductor channel region, at least one of said source and drain electrodes being formed by spaced apart regions of a first metallic material separated by regions of a second metallic material such that regions of the first and second metallic materials are in contact with the organic semiconductor channel region, said first metallic material being selected as having work function substantially similar to HOMO energy level of said organic semiconductor channel region and said second metallic material is selected as having work function substantially similar to LUMO energy level of said organic semiconductor channel region, thereby enabling selective injections of electrons or holes into said channel region.

According to some embodiments, the source and drain electrodes are formed by said spaced apart regions of said first metallic material separated by said regions of said second metallic material such that regions of the first and second metallic materials are in contact with the organic semiconductor channel region.

According to some embodiments, the transistor structure is formed as a lateral type transistor structure wherein said source and drain electrodes are spatially separated within a common layer.

According to some embodiments, the transistor structure may further comprise a gate electrode operable to apply selected gate voltage onto said channel region.

According to some embodiments, the selective injection of electrons or holes into said channel region is implemented in accordance with direction of said gate voltage.

According to some embodiments, the transistor structure may further comprise one or more alignment layers located between at least one of said source and drain electrodes and the organic semiconductor channel region, said one or more alignment layers comprising organic molecules comprising moieties having affinity to said first and second metallic materials of said at least one of said source and drain electrodes, thereby aligning work function of said first and second metallic materials with said HOMO and LUMO energy levels of said organic semiconductor channel region.

According to some embodiments, the organic semiconductor channel region may be formed by a mixture of two or more semiconductor materials, and said first and second metallic materials are selected in accordance with HOMO and LUMO energy levels of selected material compositions of the mixture of the channel region.

According to some embodiments, the transistor structure may be configured for use as a single transistor transmission gate.

According to an additional broad aspect, the present invention provides an electronic device comprising a layered structure comprising a first electrode layer, insulator layer applied on said gate electrode layer, organic semiconductor layer applied on said insulator layer and a second electrode layer applied on said organic semiconductor layer, and comprising at least two spaced apart electrodes being in electrical contact with said organic semiconductor laver, wherein at least one of said at least two spaced apart electrodes is formed by spaced apart regions of a first metallic material separated by regions of a second metallic material such that regions of the first and second metallic materials are in contact with the organic semiconductor layer, and wherein said first metallic material is selected as having work function substantially similar to HOMO energy level of said organic semiconductor layer and said second metallic material is selected as having work function substantially similar to LUMO energy level of said organic semiconductor layer, thereby enabling selective injections of electrons or holes into said organic semiconductor layer.

According to yet another broad aspect, the present invention provides an electronic device configured as an inverter unit comprising first and second ambipolar transistor units, wherein said first and second ambipolar transistor units have similar configuration as described above.

According to yet another broad aspect, the present invention provides a logic gate comprising a first and a second transistor units having similar ambipolar configuration, the first and second transistor units being electrically connected in series between selected input voltage between corresponding source and drain electrodes thereof, and an output connector is provided between said first and second transistor units and gate electrodes of the first and second transistor units being commonly connected to an input connector, such that said logic gate provides inversion of input signal.

According to yet another broad aspect, the present invention provides a transmission gate formed of a single transistor unit, said transistor unit being configured to carry out the following: block transmission of current in response to blocking control signal, allow transmission of current in one direction in response to positive addition of the control signal, allow transmission of current in another direction in response to negative addition to the control signal.

### BRIEF DESCRIPTION OF THE DRAWINGS

The patent or application file contains at least one drawing executed in color. Copies of this patent or patent application publication with color drawings will be provided by the Office upon request and payment of the necessary fee.

In order to better understand the subject matter that is disclosed herein and to exemplify how it may be carried out in practice, embodiments will now be described, by way of non-limiting example only, with reference to the accompanying drawings, in which:

FIG. 1 illustrates side view of a transistor structure configuration according to some embodiments of the present invention:

FIG. 2 exemplifies top view of a transistor structure configuration according to some embodiments of the invention;

FIGS. 3A to 3D exemplify operation of organic transistor using gold electrodes, FIG. 3A illustrated the transistor, FIGS. 3B and 3C show p- and n-type operation of the transistor, and FIG. 3D shows electron and hole mobility;

FIGS. 4A to 4D exemplify operation of organic transistor using aluminum electrodes, FIG. 4A illustrated the transistor, FIGS. 4B and 4C show p- and n-type operation of the transistor, and FIG. 4D shows electron and hole mobility:

FIG. 5 shows in Transmission electron microscope (TEM) image of island formation formed by deposition of 2 nm gold layer on DPP-T-TT polymer enabling formation of mosaic electrode according to some embodiments of the present invention:

FIG. 6 shows TEM image of 12 nm thermally deposited Al layer on top of organic semiconductor layer, the Al layer forms a continuous layer on the organic semiconductor;

FIG. 7 shows results of time-of-flight secondary ion mass spectrometry (ToF-SIMS) characterizing the depth profile of the layered structure of a transistor according to some embodiments of the invention;

FIGS. 8A to 8G exemplify gold-aluminum metal-mosaic providing source and drain electrodes of OFET, FIG. 8A illustrates top-contact bottom gate OFET, FIG. 8B shows 2D and 1D element mapping of polymer/metals interface, FIG. 8C to 8E show the n- and p-type device characteristics and distribution of gold and aluminum for gold layer thickness of respectively 5 nm, 10 nm and 15 nm topped with 12 nm aluminum, FIG. 8F shows gold covered polymer surface area with respect to the thickness, and FIG. 8G shows tuning of electron and hole mobility as a function of first gold layer thickness;

FIG. 9 shows n- and p-type output characteristic of balanced ambipolar OFET with and without energy level tuning interlayer:

FIGS. 10A to 10C show STEM EDX and X-ray photoelectron spectroscopy (XPS) measurements ensuring segregation of the additives from polymer phase to the specific metal interface:

FIGS. 11A to 11C show OFET performance for OFET configured as described above with self-generated interlayer modifying the metal mosaic source and drain electrodes:

FIGS. 12A to 12C illustrate respectively an inverter configuration, transfer characteristics and gain of a complementary-like inverter formed of two identical OFETs, and noise margin of inverter calculated from same inverter at V_{DD}=40V:

FIGS. 13A to 13C show a single ambipolar OFET based digital transmission gate operation; and

FIG. 14 shows analog phase shifter based on a single ambipolar OFET.

### DETAILED DESCRIPTION OF EMBODIMENTS

Ambipolar transistors are transistor structures capable of transporting holes and electrons, separately or concurrently, through a semiconducting channel. The operation of such ambipolar transistors requires that the semiconducting material composing it is capable of efficiently transporting both charge carriers, and requires a suitable alignment of energy levels between the semiconductor and the metal electrodes for efficient injection of both carriers from the electrodes into the semiconducting channel. Inorganic semiconducting materials, such as silicon and GaAs, can conduct either holes or electrons, depending on the type of doping. In contrast, most organic semiconducting materials with relatively narrow bandgaps (1-2 eV) can conduct electrons and holes alternatively or simultaneously.

The present invention provides a transistor structure configuration that overcomes the challenge of injecting electrons and holes into organic semiconductor channel.

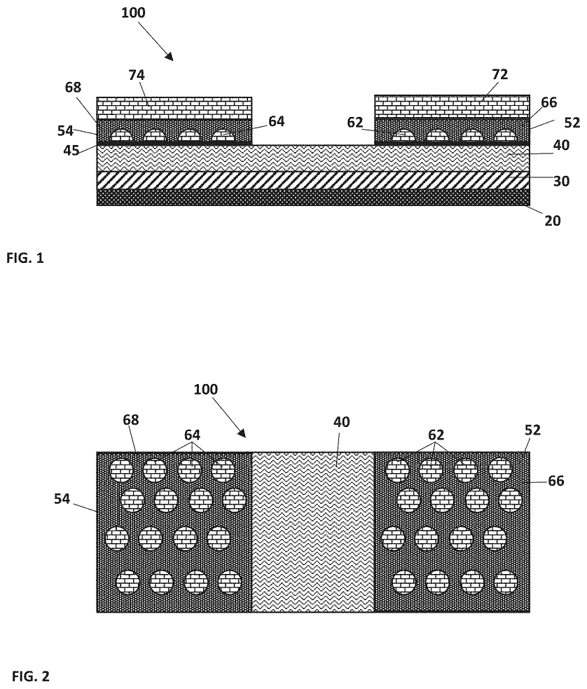

Reference is made to FIGS. 1 and 2 respectively illustrating side and top views of an exemplary transistor structure 100 according to some embodiments of the invention. The transistor structure 100 is generally configured as a lateral type transistor structure in which first 52 and second 54 electrodes are located in a common layer and are spatially separated between them. As shown in the figure, the first and second electrodes 52 and 54 are in electrical contact with a channel region 40. In the non-limiting example of FIGS. 1 and 2, both electrodes 52 and 54 are configured to interface the channel region 40 with spaced apart regions of first metallic material 62 and 64 separated by region of a second metallic material 66 and 68.

Generally, at least one of these electrodes 52 and 54 may be configured with such spaced apart arrangement of the first and second metallic materials, while the other electrode may be formed of a single metallic material. In preferred configurations, however, the first and second electrodes may be formed with patterned arrangement of first 62, 64 and second 66, 68 metallic materials.

In some configurations, the first 52 and second 54 electrodes may be covered by protective layers 72 and 74. In further some configurations (alternatively or additionally), the transistor structure 100 may also include an interlayer 45 (or interlayer segments 45) located between the organic semiconductor 40 and the first 52 and second 54 electrodes. The interlayer 45 is formed of organic or inorganic material selected to provide fine tuning to the alignment of energy levels and increase efficiency of the transistor structure 100.

The transistor structure 100 may generally be formed with a bottom electrode 20, e.g. configured to operate as a gate electrode, an insulating layer 30 separating between the bottom electrode 20 and the channel region 40.

Generally, the channel region 40 is formed of a layer of organic semiconductor material. Differently than silicon or other inorganic semiconductors, where type of doping (n-type of p-type) determines electric conductivity to electrons or holes, organic semiconductors can conduct both electrons and holes within the same material.

The first (62, 66) and second (64, 68) metallic materials of the electrode(s) (52, 54) are selected to provide alignment between work functions of the metallic materials and highest occupied molecular orbital (HOMO) and lowest unoccupied molecular orbital (LUMO) of the organic semiconductor of the channel 40. More specifically, the first metallic material (62, 66) is selected as having work function that is substantially aligned (e.g. within up to 0.4 eV difference) with HOMO energy level of the organic semiconductor material of the channel 40, and the second metallic material (64, 68) is selected as having work function that is substantially aligned (e.g. within up to 0.4 eV difference) with LUMO energy level of the organic semiconductor material of the channel. Alternatively, the first metallic material is selected to be aligned with LUMO level of the organic semiconductor and the second metallic material is selected to align with HOMO level of the organic semiconductor.

It should be noted that the transistor structure may have different configuration of the first and second metallic materials. The example of FIGS. 1 and 2 showing islands of the first metallic material (62, 64) surrounded by continuous layer of the second metallic material (66, 68) might be mostly suitable for selected manufacturing techniques as described herein below. However, the principles of the present invention are not limited to this specific configuration, and additional arrangement, such as interdigital configuration of the first and second metallic materials, may also be used to provide ambipolar transistor as described herein.

This configuration enables injection of holes from one of the first and second metallic materials into the organic semiconductor, and injection of electrons from the other metallic material into the organic semiconductor. This is based on alignment of energy levels of the channel material composition and work function associated with charge injections from the metallic material of the electrodes.

For example, in some configurations, the organic semiconductor used is DPP-T-TT polymer (PDPP2T-TT-OD) having HOMO and LUMO energy levels are respectively at 5.2 eV and 3.8 eV. Accordingly, in this example the first metallic material may be selected as gold (Au) having work function of about 5.1 eV, and the second metallic material used may be Aluminum (Al) having work function of about 4.1 eV. This selection of materials enables ambipolar operation of the transistor structure where the gold electrode regions participate in transmission of holes through the organic semiconductor of the channel and the aluminum electrode portions participate in transmission of electrons through the organic semiconductor channel 40.

In this exemplary configuration, the organic semiconductor channel is formed of high-performance ambipolar conjugated copolymer based on diketopyrrolopyrrole (DPP). This organic semiconductor provides balanced n- and p-type OFET performance, enabling selecting operation by transmission of electrons and holes using electrode configuration as described above. As mentioned, the transistor performance may be further enhanced using interlayer 45 which enables tuning of the energy level alignment. As described in more detail further below, the interlayer 45 may be provided by self-generated interlayer technique.

A variety of low bandgap conjugated polymers have been and are being developed for use in organic transistor structures. Some of such polymers are based on alternating electron donor-acceptor (D-A) units in the polymer backbone. This structure provides electron-rich and electron-deficient moieties coupled between them and reducing the bond length alternation and the band gap. Among the various organic semiconductors. Diketopyrrolopyrrole (DPP−) based semiconducting copolymers exhibit high charge-carrier mobility as well as ambipolar characteristics. In several DPP-copolymers, DPP-T-TT with thienothiophene (TT) donor moiety shows low bandgap (˜1.4 eV) and lower number of deep trap states. This provides DPP-T-TT relatively higher electron mobility along with high hole mobility.

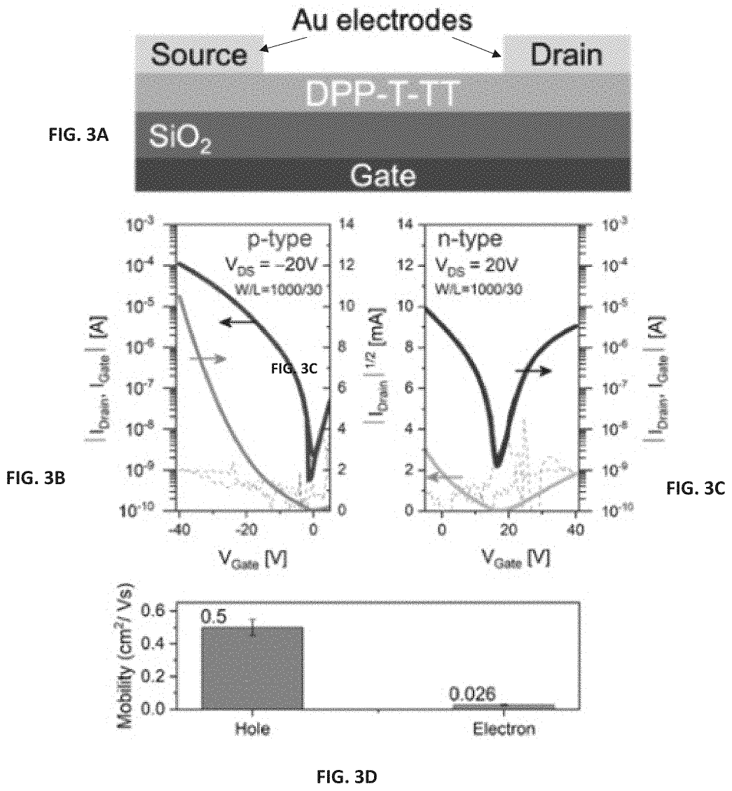

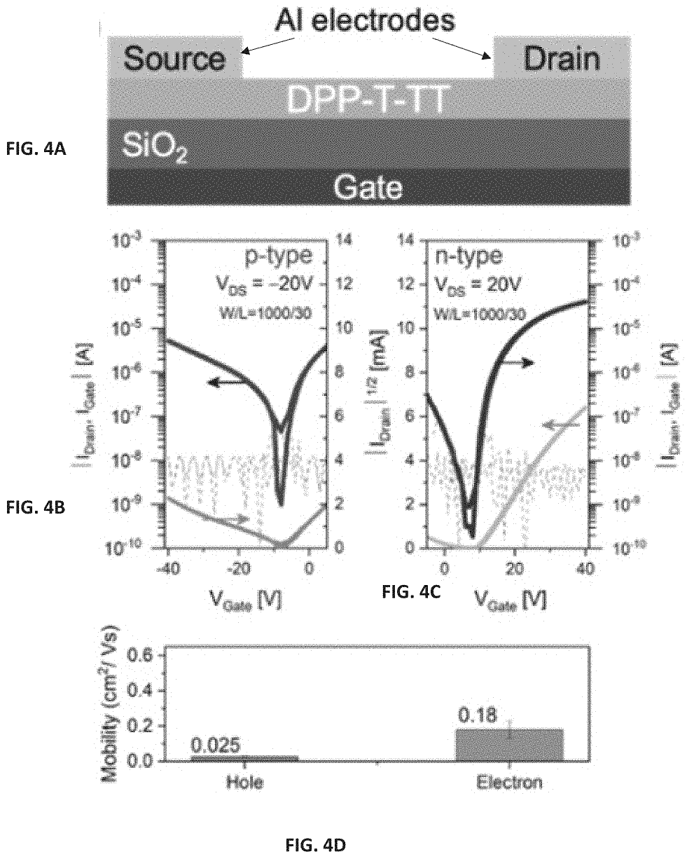

FIGS. 3A to 3D and FIGS. 4A to 4D exemplify configuration and operation of DPP-T-TT organic semiconductor in typical transistor structures using different types of electrical contacts as source and drain electrodes. FIGS. 3A and 4A exemplify transistor structures utilizing respectively gold (Au) and aluminum (Al) electrodes on the DPP-T-TT channel. FIGS. 3 and 4B show p-type operation of the transistors in transmission of holes. FIGS. 3C and 4C show n-type operation of the transistors in transmission of electrons. FIGS. 3C and 4C show comparison of charge carrier mobility in the gold and aluminum transistor configurations. As shown in these figures, the use of gold electrode provides p-type transistor and the use of aluminum electrode provides n-type transistor using similar organic semiconductor channel.

The transistor structures exemplified in FIGS. 3A and 4A are formed as Organic field effect transistors (OFET) having bottom gate and top contacts with staggered configuration. The gold (Au) electrodes are used for hole injection at the HOMO level (˜5.2 eV) of this polymer as shown in FIG. 3A. Gold has work function of 5.1 eV that is sufficiently close to the HOMO level enabling transmission of holes into the polymer.

FIGS. 3B and 3C show the p- and n-type OFET performance of the DPP-T-TT polymer with gold electrodes of FIG. 3A. As expected, these devices show high hole mobility 0.5 cm²Ns, but the electron mobility is considerably low due to higher electron injection barrier as shown in FIG. 3D. On the contrary, as shown in FIGS. 4A to 4D, OFETs with aluminum (Al) electrodes show electron mobility of about 0.2 cm²Ns (0.18 cm²/eV), but low hole mobility. The Al work function (˜4.1 eV) is close to DPP-T-TT LUMO level (˜3.8 eV), consequently the electron injection barrier is drastically reduced but the increased hole injection barrier limits the hole mobility in this device.

The inventors of the present invention have demonstrated from the comparison of these device performances with two different metal electrodes that energy level alignment of a single metal (either Au or Al) work function to the HOMO and LUMO levels of the organic semiconductor channel limits the ambipolar charge injection and hence the device performance.

Electrode configuration utilizing spaced apart regions of first and second metallic materials as described above provides for overcoming the charge injection selectivity exemplified in FIGS. 3A-3D and FIGS. 4A-4D. Such electrode configuration may be applied on surface of organic semiconductor channel by various manufacturing techniques. For example, a first continuous layer of a first metallic material may be applied on surface of the organic semiconductor channel and etched to form a selected pattern. After etching, a continuous layer of the second metallic material is applied on the pattern formed by the first metallic material. In other techniques, the first metallic material may be selectively applied through a patterned mask to form a patterned arrangement and the second metallic material may be applied on the patterned arrangement.

Additionally, the use of gold or other noble metals for forming part of the electrodes enables spontaneous islands growth. This is associated with weak interactions between the noble metals and the polymer of the organic semiconductor channel.

Accordingly, noble metals (e.g. gold) do not react with the polymer and do not wet the polymer surfaces. At thin layers, the noble metal forms clusters on bare polymer surfaces. During deposition, the noble metal atoms that adsorb on the polymer surface typically diffuse on the polymer surface for a certain time, and then desorb into vacuum or get trapped somewhere on or beneath the polymer surface. The trapped metal atoms form nucleation sites and gradually develop metal clusters. The distance between nucleation sites depends on the probability to find trap sites and the diffusion length of the adatoms on the polymer surface. Such island like growth of gold has been shown to be a function of thickness on the organic semiconducting polymer.

FIG. 5 shows a Transmission Electron Microscope (TEM) image of island formation resulting from deposition of 2 nm gold layer on DPP-T-TT polymer. Gold has higher atomic number as compared to carbon, therefore in bright field TEM image the gold clusters appeared as dark islands on a brighter background of carbon based DPP-T-TT polymer. Apparently, if a second metal is deposited on the top of this partially gold covered polymer surface, the bare polymer surface (the bright regions of FIG. 5) gets covered by that second metal.

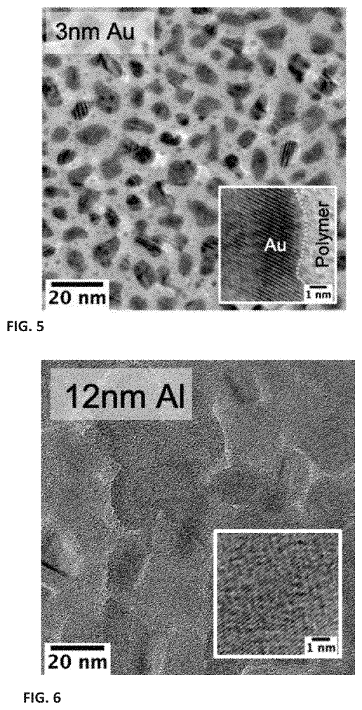

In this exemplary configuration, the second metallic material is selected as aluminum (Al). FIG. 6 shows TEM image of 12 nm thermally deposited Al layer. The Al layer fully covers the DPP-T-TT polymer surface and the gold islands. In this process, both metals form a metallic mosaic pattern on the polymer surface, i.e. some area of the DPP-T-TT polymer is in the direct contact with gold and other areas are in contact with the aluminum.

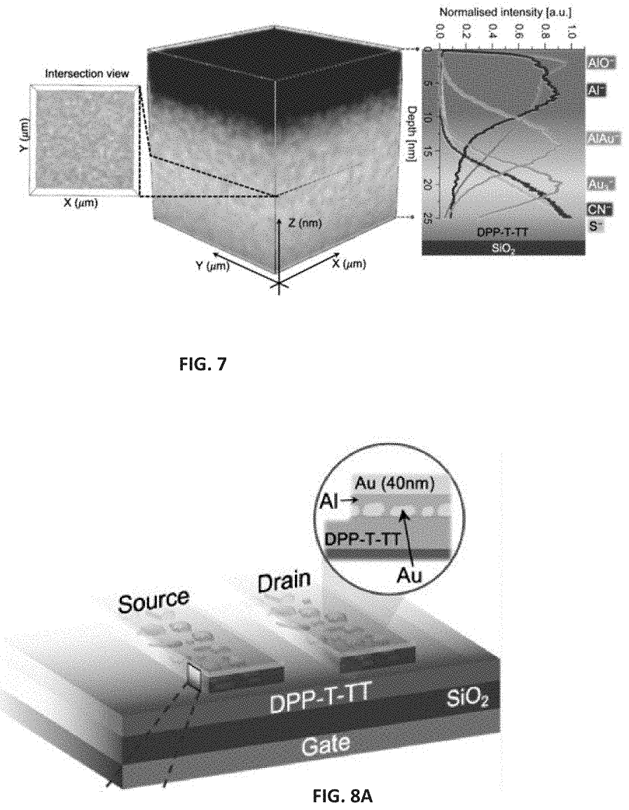

To investigate the distribution of the metal layers on the polymer surface, FIG. 7 shows results of time-of-flight secondary ion mass spectrometry (ToF-SIMS) characterizing the depth profile of the layered structure Al (12 nm)/Au (5 nm)/DPP-T-TT. The 3D ToF-SIMS depth profile of FIG. 7 shows aluminum (top), gold (middle) and polymer (bottom) regions, which are quantitatively represented in the 1D plot of FIG. 7. In the 1D ToF-SIMS plot. CN⁻ and S⁻ ions represent the DPP-T-TT polymer. The thin gold layer (Au₃⁻) is clearly present next to the polymer layer and the top aluminum layer (Al⁻, AlO⁻) is extended up to the polymer. More interestingly, the AlAu⁻ ions (orange) which is the signature of mixed gold and aluminum in more strongly present at the polymer interface. This is supported by the 2D scan of an intersection plane close to the polymer/metal interface showing the presence of aluminum or Al—Au mixed regions with a gold background.

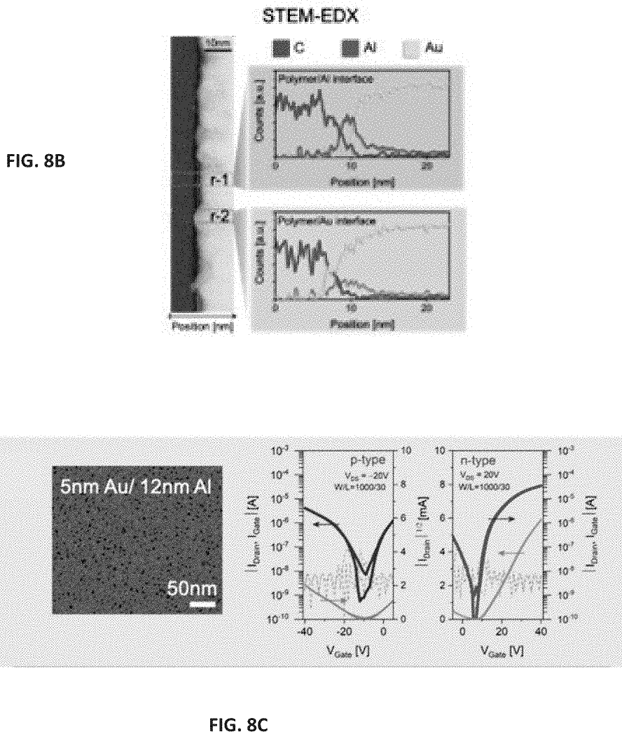

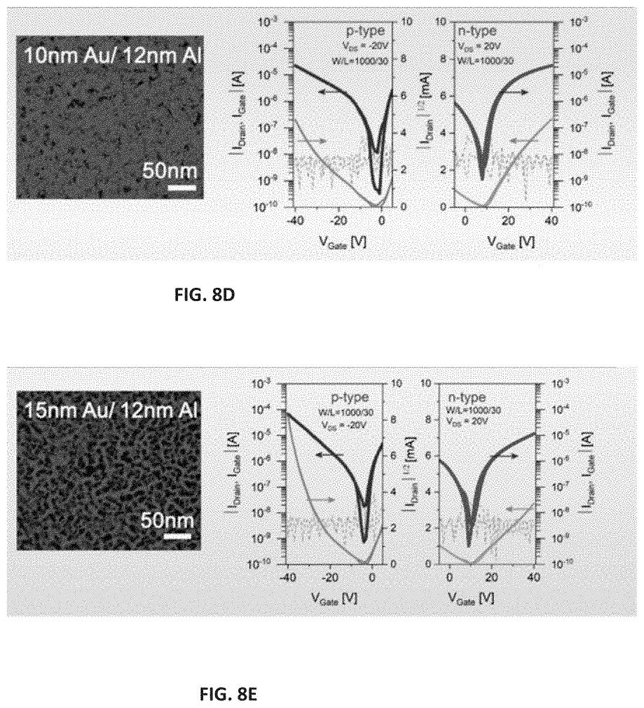

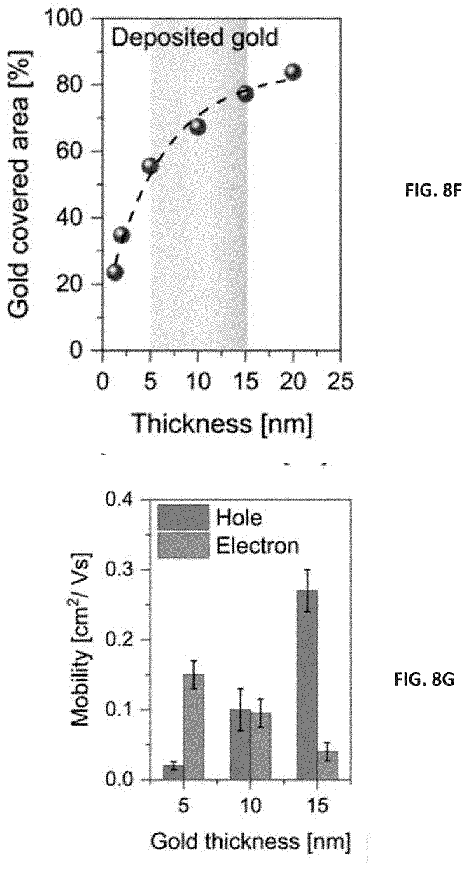

Reference is made to FIGS. 8A to 8G exemplifying gold-aluminum metal-mosaic providing source and drain electrodes of OFETs to achieve balanced ambipolar performance. FIG. 8A illustrates top-contact bottom gate device with metal-mosaic source and drain electrodes. The schematic of metal layers is shown in inset in the figure. FIG. 8B shows 2D and 1D element mapping of polymer/metals interface characterized by STEM-EDX at a cross-sectioned OFET device with metal-mosaic electrodes. The 1D plot shows the distribution of gold and aluminum at continuous gold region (r-1) and continuous aluminum region (r-2). FIG. 8C to 8E show the n- and p-type device characteristics and distribution of gold and aluminum for gold layer thickness of respectively 5 nm, 10 nm and 15 nm topped with 12 nm aluminum. FIG. 8F shows gold covered polymer surface area with respect to the thickness. FIG. 8G shows tuning of electron and hole mobility as a function of first gold layer thickness.

The patterned electrodes in the example of FIG. 8A include an additional 30-40 nm gold top protection layer. Characterization of the metal/polymer interface is shown in FIG. 8B indicating DPP-T-TT/Au (5 nm)/Al (12 nm)/Au (30 nm) interface using cross-section STEM elemental mapping. This characterization shows regions of Au/polymer interface and regions of Al/polymer interface. The 2D STEM-energy dispersive X-ray spectroscopy (STEM-EDX) elemental mapping quantitatively shows the carbon fingerprint of organic semiconducting polymer film alternatively in contact with gold and aluminum. The 1D plot of region r-1 clearly shows the polymer aluminum interface where the gold count has reduced drastically. On the contrary, at the subsequent region r-2, the aluminum count is lower than the gold count and the gold is clearly in direct contact to the polymer.

Following this element mapping, the inventors have demonstrated that DPP-TT-T semiconductor regions which are directly in contact of gold, efficiently inject the hole to the HOMO level. Likewise, the semiconductor regions, which are in direct contact with aluminum, efficiently inject electron to the LUMO level. Eventually, the ratio of Au and Al covered area controls the effective performance of the n- and p-type performance of the device.

Transistor performance as n- and p-type OFETs with the first gold layer thickness 5, 10 and 15 nm followed by a 12 nm Al layer, as well as mapping of the gold-covered polymer area for that corresponding gold layer thicknesses using TEM technique, are shown in FIGS. 8C to 8E respectively. As shown, in the 5 nm gold sample topped by 12 nm aluminum, the gold and aluminum phases are nearly continuous, and the gold covered polymer area is about 55% (FIG. 8F). However, the OFET performance shows dominant n-type behavior with higher electron mobility as shown in FIG. 8G. When the gold layer thickness was raised to 10 nm, the gold and aluminum phases were fully bi-continuous (FIG. 8D) and the gold cover area is increased to 70%. Both metals domain sizes were increased and became comparable with respect to the lower gold thickness samples. The OFETs showed nicely balanced n- and p-type performances with similar electron and hole mobilities. Further increase of gold layer thickness enhances the hole mobility due to increasing continuous gold covered polymer area, as shown for 15 nm gold layer sample in FIG. 8E. This, as well as additional TEM micrographs of other lower and higher gold layer thickness samples, indicate that the metal-mosaic electrode comprised of 10 nm gold/12 nm aluminum inject electron and hole uniformly in DPP-T-TT polymer and depending on the biasing condition OFET device shows balanced n and p-type performance. It should be noted that alternative material selection may provide similar results with different layer thicknesses.

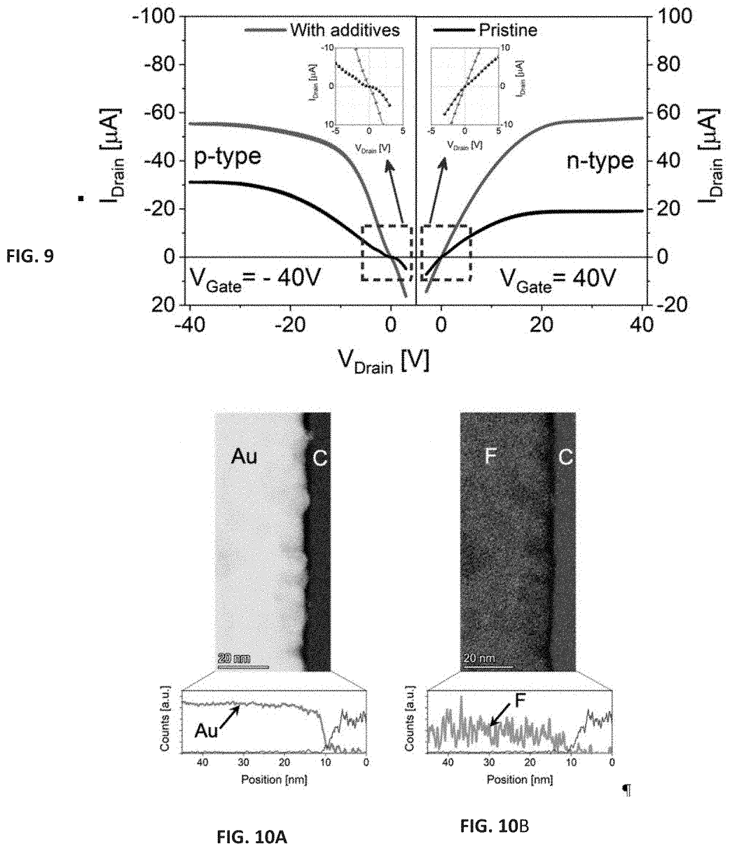

Reference is made to FIG. 9 illustrating n- and p-type output characteristic of balanced ambipolar OFET using pristine metal mosaic (PMM) electrodes with self-generated interlayer (with additives) and modified metal mosaic (MMM) electrodes. As shown, the drain current at low source-drain voltages indicates nonlinear behavior associated with non-ohmic organic-metal contact. This is a result of energy level mismatch at metal work-function and semiconductor energy level. Therefore, it indicates that due to the mismatch of energy levels, aluminum and gold do not form an ohmic contact with the LUMO and HOMO level of the DPP-T-TT, respectively. A practical approach for optimizing metallorganic interface is tuning the work-function of the metal electrodes. Tuning the effective work function (EWF) at the organic/metal interface can be done by introducing ultrathin organic or inorganic interlayers between the metal contact and the organic semiconductor.

In this connection, the inventors of the present invention have developed an energy level alignment method utilizing self-segregated interlayers. This technique is especially useful in alignment of energy levels in top-contact organic electronic devices. To this end, molecules with moieties that have affinity to the electrode metal, for example, O—H to Aluminum or S—H to gold, are initially blended as additives in the semiconducting polymer film. These molecules spontaneously migrate to the polymer/metal interface during metal deposition. Additive migration stops once a complete interlayer is formed fully covering the metal contact, and the driving force for migration is terminated. During the migration process, the bulk film is depleted of the additive molecules which are now situated at the polymer/metal interface. In the present example of DPP-T-TT channel using mosaic electrodes formed by gold and aluminum, the inventors used 4-fluoro benzyl mercaptan (4-FM) and polyethylene glycol (PEG) for forming these interlayers. Both additives were implemented to form PEG interlayer at the aluminum/organic interface and 4-FM interlayer at the gold/organic interface.

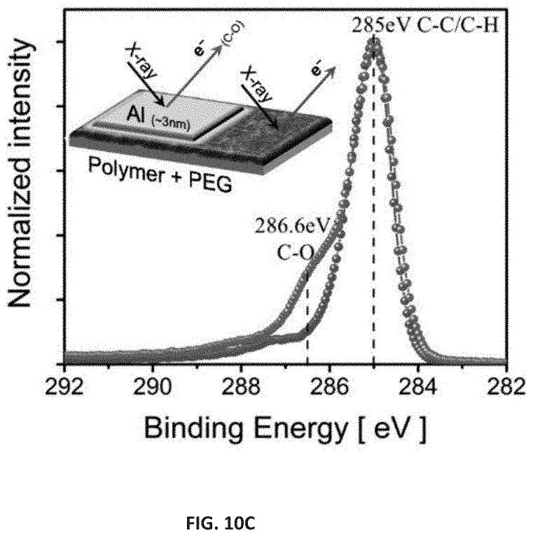

FIGS. 10A to 10C show STEM EDX and X-ray photoelectron spectroscopy (XPS) measurements ensuring segregation of the additives from polymer phase to the specific metal interface. FIGS. 10A and 10B show STEM DEX mapping of edges of gold/polymer interface region showing the coexistence of gold (Au) and fluorine (F) at the same position of the sample. In this case fluorine is used as a marker for 4-FM. FIG. 10C shows XPS measurements performed on a bare region (not covered by Al) and an Al-covered region of the polymer channel. The XPS spectra of the bare and aluminum covered regions of PEG mixed DPP-T-TT film shows C1s peak at 285 eV, characteristic of the C—C/C—H bonds of the polymer. However, the XPS spectra of aluminum covered regions show an additional C—O peak at 286.45 eV, which is the fingerprint of PEG molecule. The presence of C—O fingerprint of PEG molecule exclusively at the Al/polymer interface unambiguously confirm migration of PEG molecules to the Al/polymer interface and the self-generation of a PEG interlayer at the organic/Al interface.

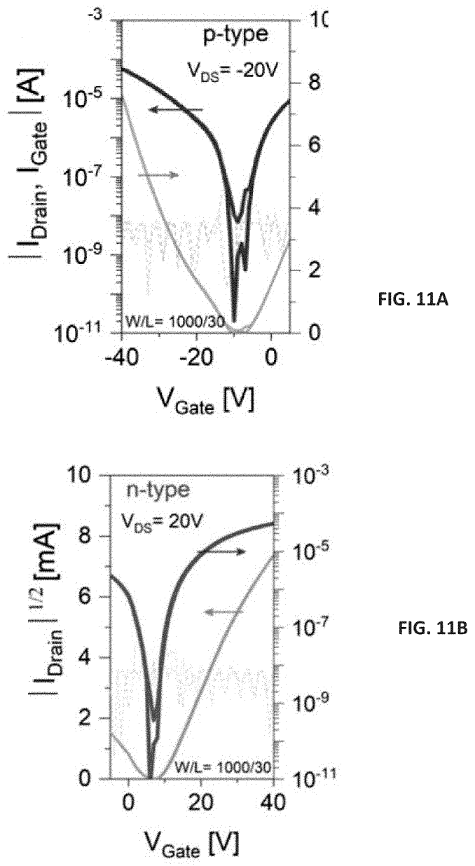

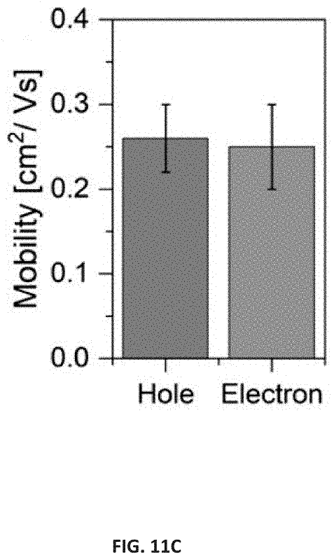

Reference is made to FIGS. 11A to 11C showing OFET performance for OFET configured as described above with self-generated interlayer modifying the metal mosaic source and drain electrodes. FIGS. 11A and 11B show respectively n- and p-type transfer characteristics for drain voltage 20V; and FIG. 11C shows the average electron and hole mobilities calculated from ten similar devices. The overall drain current is enhanced compared to the pristine metal-mosaic ambipolar OFETs that does not use the interlayer. At the output characteristics shown in FIG. 9, the depression of drain current at the low drain voltage is removed for both n- and p-type operation of devices and metal/organic interface became more ohmic by reducing the contact resistance.

Device parameters for the different transistor configurations are listed in table 1. Consequently, the electron and hole mobilities in the ambipolar transistor described herein using energy level tuning interlayer were doubled compared to the pristine devices, as shown in FIG. 11C.

TABLE 1

| | | | Threshold | | | | ON/OFF | |
|---|---|---|---|---|---|---|---|---|
| | | | Voltage | | | | (@V_{Drain} = | |
| | | | [V] | | Mobility (cm²/Vs) | | ±20V) | |
| No. Of | Type of | | p- | n- | (@ V_{Gate} = ±40V) | | p- | n- |
| devices | electrodes | Additives | type | type | μₕ | μₑ | type | type |
| 10 | Only Au | No | −11 | 18 | 0.5 | 0.026 | 10⁵ | 10⁴ |
| | | | | | (±0.03) | (±0.005) | | |
| 8 | Only Al | No | −11.8 | 10.5 | 0.025 | 0.18 | 10³ | 10⁵ |
| | | | | | (±0.003) | (±0.05) | | |
| 7 | 5 nm Au:12 Al: | No | −12.5 | 10.5 | 0.02 | 0.15 | 10³ | 10⁵ |
| | 30 nm Au | | | | (±0.006) | (±0.03) | | |
| 8 | 10 nm Au:12 Al: | No | −5 | 8 | 0.1 | 0.095 | 10⁴ | 10⁴ |
| | 30 nm Au | | | | (±0.03) | (±0.02) | | |
| 4 | 15 nm Au:12 Al: | No | −13 | 10.4 | 0.27 | 0.04 | 10⁵ | 10⁴ |
| | 30 nm Au | | | | (±0.04) | (±0.013) | | |
| 12 | 10 nm Au:12 Al: | Yes | −14.5 | 9.7 | 0.26 | 0.25 | 10⁶ | 10⁶ |
| | 30 nm Au | | | | (±0.04) | (±0.05) | | |

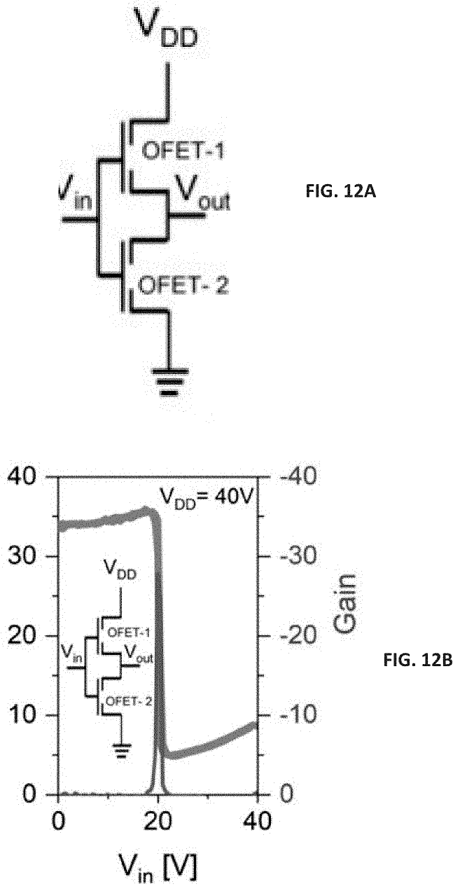

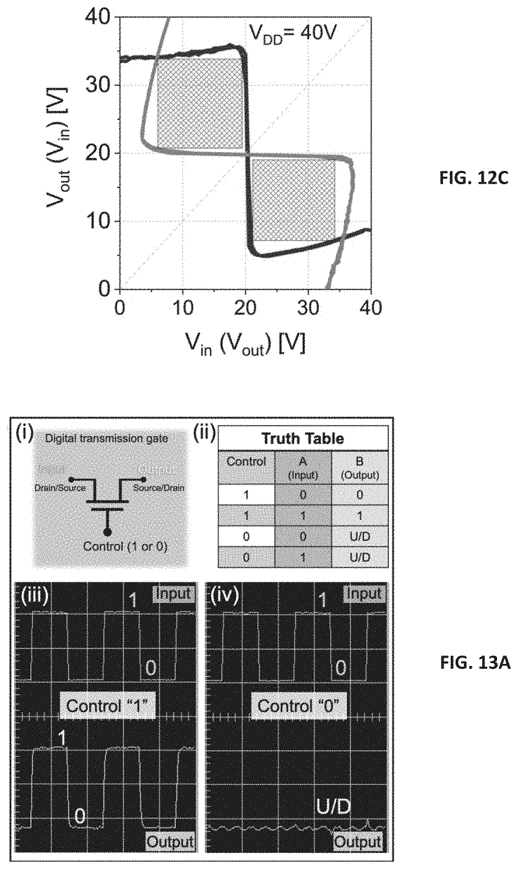

The properties of ambipolar transistor structure configured according to the present technique enable fabrication of further electronic devices. Reference is made to FIGS. 12A and 12C illustrating respectively an inverter configuration, transfer characteristics and gain of a complementary-like inverter formed of two identical OFETs. and noise margin of inverter calculated from same inverter at V_{DD}=40V. In this example, the OFETs are formed with dimensions of L=30 μm W=1000 μm. The inverter formed of two identical transistors (OFETs) enables balanced characterization of n- and p-type performance of the ambipolar OFETs were characterized by fabricating the inverters using two identical OFETs. In this example, the switching voltage (Vₒᵤₜ=Vᵢₙ) of the inverter is at 20V, which is exactly V_{DD}/2, it indicates perfectly balanced n- and p-type performance of each ambipolar OFETs. The average gain of the inverter is ˜30 with a noise margin ˜13.3 V at V_{DD}=40V (shown in FIG. 12C), which is approximately 65% of its theoretical limit (V_{DD}/2).

After characterizing the ambipolar behavior with reasonable electron mobility and hole mobility, the inventors employed the ambipolar OFETs described herein in digital and analog applications simple circuit design.

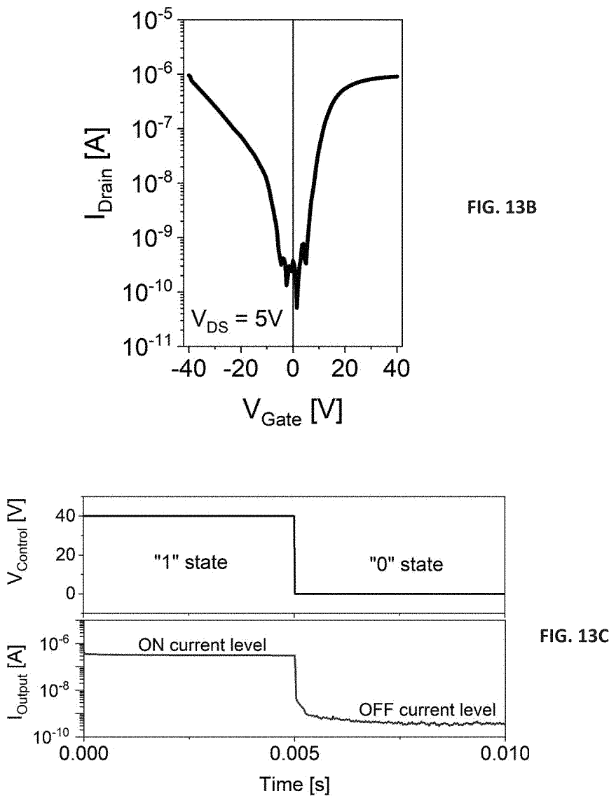

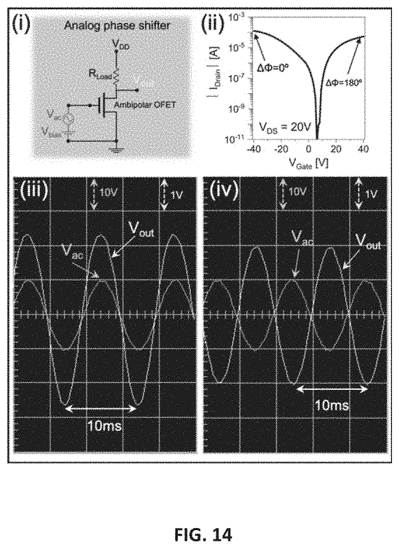

FIGS. 13A to 13C and 14 illustrate the circuit design and their performance. FIG. 13A shows a single ambipolar OFET based digital transmission gate operation, (i) represents the circuit diagram, (ii) the logic table, and (iii) and (iv) represent the digital operations for control “I” and “0” respectively, FIG. 13B shows IV curve of the single ambipolar transistor for positive and negative gate voltages, and FIG. 13C shows a comparison between current levels at ON and OFF states of the transistor. FIG. 14 shows analog phase shifter based on a single ambipolar OFET and a 100 KΩ resistor, (i) represents the circuit diagram, (ii) shows the ambipolar transfer characteristic of the OFET, and (iii) and (iv) represent the input and output sinusoidal signals with zero phase difference and 180° phase difference for negative and positive bias voltage respectively.

Digital transmission gates are widely used in digital logic circuits of several digital electronic devices, e.g. multiplexers, Field Programmable Gate Arrays (FPGAs) etc. A conventional digital transmission gate circuit requires one n-type and one p-type field effect transistors (FET) along with an inverter which requires another two FETs (one n-type and one p-type). Therefore, in total, four FETs are required to realize transmission gate logic. The present technique, utilizing ambipolar transistor units, enables correct logic behavior of the transmission gate through dynamic characterizations. This is exemplified herein by feeding a 100 Hz square pulse to the input of the transmission gate and recording the waveforms at the output node as shown in FIGS. 13A to 13C, using transistor devices having identical configurations. When the control terminal (e.g. gate) is at state “1” (e.g. 40V), the ambipolar OFET of the present technique is ON and the output follows the input voltage, the transmission gate acts as a short circuit with a relatively small resistance between source and drain contacts (FIG. 13A iii). On the contrary, when the control terminal is at state “0” (e.g. grounded), the ambipolar OFET is OFF and then the output is disconnected from the input terminal and remains in “undefined” (U/D) state (FIG. 13A iv). As shown in FIG. 13B, the drain current may be positive or negative in accordance with sign of the gate voltage, providing the input signal of the control terminal. FIG. 13C shows levels of ON and OFF currents for respective ON and OFF states. As shown, the transistor transmits very low current at the OFF state, providing low power consumption and high efficiency at static states. Due to non-polar device configuration, the source and drain electrodes of the ambipolar OFETs are interchangeable, which allows to realize bilateral switching behavior of the transmission gate using a single transistor unit. The example of FIGS. 13A to 13C illustrates a transmission gate formed of a single transistor unit in accordance with some embodiments of the present invention. As shown, the transmission gate allows current flow in one direction, another direction or blocking current in accordance with direction of the control signal (gate voltage). In this example, the zero bias control signal is exemplified at zero gate voltage.

Analog application and performance for analog phase shifting circuit based on above discussed ambipolar OFETs are exemplified in FIG. 14. The schematic of the ambipolar OFET based phase shifting amplifier circuit is shown in FIG. 14 i, where the supply voltage V_{DD} is set to 40 V, and the load resistor (R_{load}) is 100 kW. As seen, the gate voltage (V_{gate}=Vᵢₙ) is equal to the sum of a fixed DC bias voltage (V_{bias}) and a small sinusoidal AC signal (V_{ac}, Vₚₚ=10V, frequency=100 Hz). The transfer characteristics of the ambipolar transistor is shown in figure FIG. 14 ii, which shows balance electron and hole transport at drain voltage 20V. The output signal (Vₒᵤₜ) was recorded by an oscilloscope as shown in FIG. 14 iii & iv corresponding to negative and positive V_{bias}, respectively. When a negative V_{bias} is applied to the ambipolar OFET amplifier (FIG. 14 iii), at the positive phase of V_{ac}, I_{ds} increases/decreases as V_{gate} decreases/increases, therefore, the corresponding Vₒᵤₜ also increases/decreases in an oscillatory manner. This is called the common-drain mode when the output signal remains in the same phase as the input signal. In contrast, when V_{bias} is in the n-type regime, the amplifier is in common-source mode when the Vₒᵤₜ oscillates synchronously with a phase difference of 1800 with respect to V_{gate}, as shown in FIG. 14 iv. Following the same operational principle, when the biasing voltage was swept from negative to positive 40V, the phase difference was also tuned zero to 180° through the other intermediate phase showing suitable performance of the OFET.

Accordingly, the present technique provides a transistor structure configuration and variety of electronic devices utilizing such transistor configuration. The transistor structure is configured as ambipolar transistor capable of transmission of electrons and holes and thus to switch its operation direction in accordance with gate voltage variation. The transistor structure utilizes mosaic metal electrodes formed by regions of first and second metallic materials, where one metallic material has work function near HOMO level of organic semiconductor and the other metallic material has work function near LUMO level of the organic semiconductor. Using these electrodes as source and drain provides truly balanced ambipolar OFET performance, which showed nearly ideal inverter performance. Finally, implementing the ambipolar OFET in digital transmission gate and analog phase shifter application shows the versatile applicability of ambipolar OFETs with metal mosaic electrodes. Successfully implementing the metal-mosaic electrode for ambipolar charge injection in OFET devices, the present invention introduces a new concept of electrode which can also be implement for any other ambipolar device such as, light emitting transistors, memory devices etc.

1. A transistor structure comprising: an organic semiconductor channel region, and source and drain electrodes in electrical contact with said organic semiconductor channel region, wherein at least one of said source and drain electrodes is formed by spaced apart regions of a first metallic material separated by regions of a second metallic material such that regions of the first and second metallic materials are in contact with the organic semiconductor channel region, said first metallic material being selected as having work function substantially similar to HOMO energy level of said organic semiconductor channel region and said second metallic material being selected as having work function substantially similar to LUMO energy level of said organic semiconductor channel region, thereby enabling selective injections of electrons or holes into said channel region.

2. The transistor structure of claim 1, wherein said source and drain electrodes are formed by said spaced apart regions of said first metallic material separated by said regions of said second metallic material such that regions of the first and second metallic materials are in contact with the organic semiconductor channel region.

3. The transistor structure of claim 1, configured as a lateral type transistor structure, wherein said source and drain electrodes are spatially separated within a common layer.

4. The transistor structure of claim 1, further comprising a gate electrode operable to apply selected gate voltage onto said channel region.

5. The transistor structure of claim 4, wherein said selective injections of electrons or holes into said channel region is selected in accordance with direction of said gate voltage.

6. The transistor structure of claim 1, further comprising one or more alignment layers located between at least one of said source and drain electrodes and the organic semiconductor channel region, said one or more alignment layers comprise organic molecules comprising moieties having affinity to said first and second metallic materials of said at least one of said source and drain electrodes, thereby aligning work function of said first and second metallic materials with said HOMO and LUMO energy levels of said organic semiconductor channel region.

7. The transistor structure of claim 1, configured as a single transistor transmission gate.

8. An electronic device comprising the transistor structure of claim 1.

9. An electronic device comprising: a layered structure comprising a first electrode layer, insulator layer applied on said gate electrode layer, organic semiconductor layer applied on said insulator layer, and a second electrode layer applied on said organic semiconductor layer; and comprising at least two spaced apart electrodes being in electrical contact with said organic semiconductor layer, wherein at least one of said at least two spaced apart electrodes is formed by spaced apart regions of a first metallic material separated by regions of a second metallic material such that regions of the first and second metallic materials are in contact with the organic semiconductor layer, and wherein said first metallic material is selected as having work function substantially similar to HOMO energy level of said organic semiconductor layer and said second metallic material is selected as having work function substantially similar to LUMO energy level of said organic semiconductor layer, thereby enabling selective injections of electrons or holes into said organic semiconductor layer.

10. The electronic device of claim 9, wherein said at least two spaced apart electrodes are formed by said spaced apart regions of said first metallic material separated by said regions of said second metallic material such that regions of the first and second metallic materials are in contact with the organic semiconductor layer.

11. An electronic device configured as an inverter unit comprising first and second ambipolar transistor units, wherein said first and second ambipolar transistor units have similar configuration in accordance with claim 1.

12. An logic gate comprising: a first and a second transistor units having similar ambipolar configuration, the first and second transistor unit are electrically connected in series between selected input voltage between corresponding source and drain electrodes thereof, an output connector between said first and second transistor units, and gate electrodes of the first and second transistor units commonly connected to an input connector, such that said logic gate provides inversion of an input signal.

13. A transmission gate comprising a single transistor unit, said transistor unit being configured to carry out the following: block transmission of current in response to a blocking control signal, allow transmission of current in one direction in response to positive addition of the control signal, and allow transmission of current in another direction in response to negative addition to the control signal.
